(19) United States
(12) Patent Application Publication
(10) Pub. No.: US 2026/0164995 A1
(43) Pub. Date: Jun. 11, 2026

(54) DISPLAY DEVICE

(71) Applicant: LG Display Co., Ltd., Seoul (KR)

(72) Inventor: DongHun JUNG, Paju-si (KR)

(73) Assignee: LG Display Co., Ltd., Seoul (KR)

(21) Appl. No.: 19/315,093

(22) Filed: Aug. 29, 2025

(30) Foreign Application Priority Data
Dec. 11, 2024 (KR) 10-2024-0183997

(51) Int. Cl. H10K 59/80; H10K 59/131; H10K 59/40; G06F 3/041

(52) U.S. Cl. CPC H10K 59/873; H10K 59/131; H10K 59/40; G06F 3/0412

(57) ABSTRACT

A display device can include a substrate including a display area and a non-display area configured to be adjacent to the display area, a plurality of light-emitting elements disposed in the display area on the substrate, a protective layer disposed at an outermost periphery of the non-display area on the substrate and having an inclined surface inclined inward, a plurality of touch electrodes disposed on the plurality of light-emitting elements, a conductive pattern disposed on the protective layer in the non-display area, a touch insulation layer disposed on the plurality of touch electrodes and the conductive pattern, and a planarization layer disposed on the touch insulation layer.

### CROSS-REFERENCE TO RELATED APPLICATIONS

This application claims priority to Korean Patent Application No. 10-2024-0183997 filed on December 11, 2024, in the Korean Intellectual Property Office, the entire contents of which is hereby expressly incorporated by reference into the present application.

### BACKGROUND

### Field

The present disclosure relates to a display device, and more particularly, to a display device capable of minimizing the occurrence and propagation of a crack at an outermost periphery of a display panel.

### Description of the Related Art

Display devices, which visually display electrical information signals, are being rapidly developed in accordance with the entry into the information era. Various studies are being continuously conducted to develop a variety of display devices which are thin and lightweight, consume low power, and have improved performance.

As the representative display devices, there can be a liquid crystal display device (LCD), a field emission display device (FED), an electrowetting display device (EWD), an organic light-emitting display device (OLED), and the like.

An electroluminescent display device, as the representative organic light-emitting display device, refers to a display device that autonomously emits light. Unlike a liquid crystal display device, the electroluminescent display device does not require a separate light source and thus can be manufactured as a lightweight, thin display device. In addition, the electroluminescent display device is advantageous in terms of power consumption because the electroluminescent display device operates at a low voltage. Further, the electroluminescent display device is expected to be adopted in various fields because the electroluminescent display device is also excellent in implementation of colors, response speeds, viewing angles, and contrast ratios (CRs).

### SUMMARY OF THE DISCLOSURE

An object to be achieved by the present disclosure is to provide a display device capable of minimizing the occurrence of a crack caused by contraction of an organic material at an outermost periphery of a display panel.

Another object to be achieved by the present disclosure is to provide a display device capable of minimizing the propagation of a formed crack to a display area even though the crack occurs at an outermost periphery of a display panel.

Still another object to be achieved by the present disclosure is to provide a low-power display device capable of minimizing the occurrence and propagation of a crack at an outermost periphery of a display panel, improving reliability of the display device, improving a lifespan, and reducing power consumption.

Objects of the present disclosure are not limited to the above-mentioned objects, and other objects, which are not mentioned above, can be clearly understood by those skilled in the art from the following descriptions.

A display device according to an embodiment of the present disclosure includes: a substrate including a display area and a non-display area configured to surround the display area; a plurality of light-emitting elements disposed in the display area on the substrate; a protective layer disposed at an outermost periphery of the non-display area on the substrate and having an inclined surface inclined inward; a plurality of touch electrodes disposed on the plurality of light-emitting elements; a conductive pattern disposed on the protective layer in the non-display area; a touch insulation layer disposed on the plurality of touch electrodes and the conductive pattern; and a planarization layer disposed on the touch insulation layer.

A display device according to another embodiment of the present disclosure includes: a substrate including a display area in which a plurality of subpixels are disposed, a non-display area configured to surround the display area, and a bending area extending from one side of the non-display area and bent; a plurality of light-emitting elements respectively disposed in the plurality of subpixels on the substrate; a plurality of dams disposed in the non-display area on the substrate and disposed to surround the display area; a protective layer disposed outward of an outermost peripheral dam among the plurality of dams on the substrate and disposed to be spaced apart from the bending area; a plurality of touch electrodes disposed on the plurality of light-emitting elements; a conductive pattern disposed in the non-display area and disposed to extend from the inside of the outermost peripheral dam to a top surface of the protective layer; a touch insulation layer disposed on the plurality of touch electrodes and the conductive pattern; and a planarization layer disposed on the touch insulation layer.

Other detailed matters of the example embodiments of the present disclosure are included in the detailed description and the drawings.

According to the display device of the present disclosure, it is possible to improve the reliability of the display device by minimizing the occurrence of a crack at the outermost periphery of the display panel.

According to the display device of the present disclosure, it is possible to improve the display quality of the display device by minimizing the propagation of a crack occurring at the outermost periphery of the display panel to the display area.

According to the display device of the present disclosure, the occurrence and propagation of a crack at the outermost periphery of the display panel can be minimized, thereby improving the reliability and lifespan of the display device and implementing a low-power display device with reduced power consumption.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1A is a top plan view of a display device according to one or more embodiments of the present disclosure;

FIG. 1B is an enlarged top plan view of area A in FIG. 1A according to one or more embodiments of the present disclosure;

FIG. 1C is an enlarged top plan view of area B in FIG. 1A according to one or more embodiments of the present disclosure;

FIG. 1D is an enlarged top plan view of area C in FIG. 1A according to one or more embodiments of the present disclosure;

FIG. 2 is a cross-sectional view taken along line D-D' in FIG. 1A according to one or more embodiments of the present disclosure;

FIG. 3 is a cross-sectional view taken along line E-E' in FIG. 1A according to one or more embodiments of the present disclosure;

FIG. 4 is an enlarged cross-sectional view of area F in FIG. 2 according to one or more embodiments of the present disclosure;

FIG. 5 is a cross-sectional view for explaining a case in which the display device according to one or more embodiments of the present disclosure partially contracts; and

FIG. 6 is a cross-sectional view of a display device according to another embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as 'including', 'having', 'consist of' used herein are generally intended to allow other components to be added unless the terms are used with the term 'only'. Any references to singular can include plural unless expressly stated otherwise.

Components are interpreted to include an ordinary error range even if not expressly stated.

When the position relation between two parts is described using the terms such as 'on', 'above', 'below', 'next', one or more parts can be positioned between the two parts unless the terms are used with the term 'immediately' or 'directly'.

When an element or layer is disposed "on" another element or layer, another layer or another element can be interposed directly on the other element or therebetween.

Although the terms "first", "second", and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated. Further, the term “can” fully encompasses all the meanings and coverages of the term “may” and vice versa.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings. All the components of each display device/apparatus according to all embodiments of the present disclosure are operatively coupled and configured.

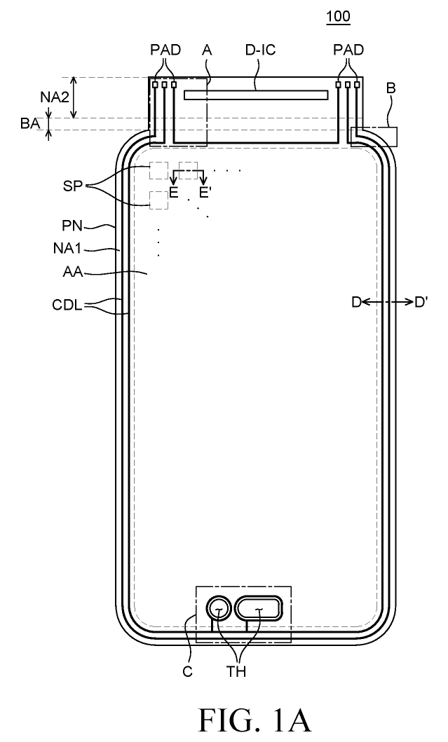

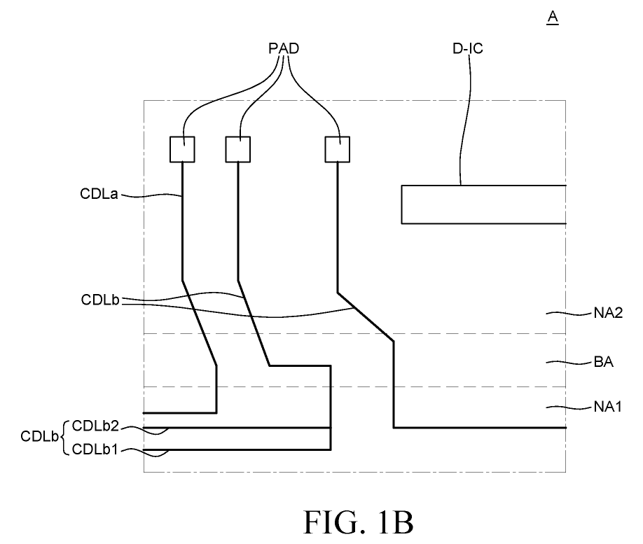

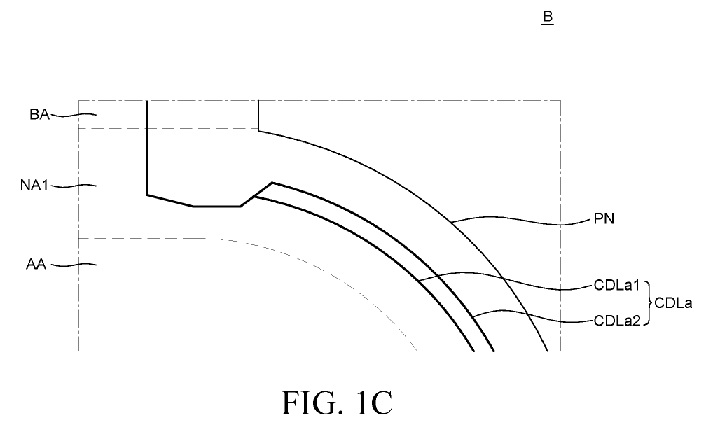

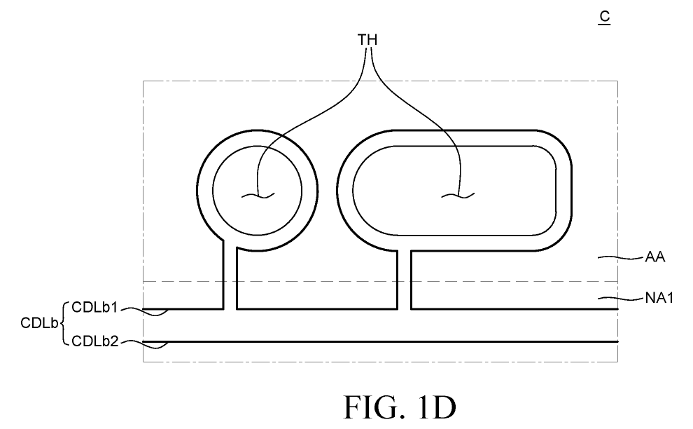

FIG. 1A is a top plan view of a display device according to an embodiment of the present disclosure. FIG. 1B is an enlarged top plan view of area A in FIG. 1A. FIG. 1C is an enlarged top plan view of area B in FIG. 1A. FIG. 1D is an enlarged top plan view of area C in FIG. 1A. Specifically, FIGS. 1B and 1C are enlarged top plan views for explaining a plurality of crack detection lines, and FIG. 1D is an enlarged top plan view for explaining through-holes disposed in a display area. Meanwhile, for convenience of description, FIG. 1C illustrates lower detection lines among the plurality of crack detection lines.

Referring to FIGS. 1A to 1D, a display device 100 includes a display panel PN, and the display panel PN is a panel configured to display images to users. The display panel PN can include a display element configured to display images, a driving element configured to operate the display element, and lines configured to transmit various types of signals to the display element and the driving element.

The display elements can be differently defined depending on the type of display panel PN. For example, in a case in which the display panel PN is an organic light-emitting display panel PN, the display element can be an organic light-emitting element including an anode, an organic light-emitting layer, and a cathode. For example, in a case in which the display panel PN is a liquid crystal display panel, the display element can be a liquid crystal display element. Hereinafter, the assumption is made that the display panel PN is the organic light-emitting display panel. However, the display panel PN is not limited to the organic light-emitting display panel.

The display panel PN includes a display area (or active area) AA and a non-display area (or non-active area) which can surround the display area AA entirely or only in part(s).

The display area AA is an area of the display panel PN in which images are displayed. The display area AA can include a plurality of subpixels SP constituting a plurality of pixels, and a drive circuit configured to operate the plurality of subpixels SP.

The plurality of subpixels SP can be minimum units that constitute the display area AA. The display elements can be respectively disposed in the plurality of subpixels SP. For example, the plurality of subpixels SP can each include a light-emitting element including an anode, a light-emitting layer, and a cathode. However, the present disclosure is not limited thereto. In addition, the drive circuit configured to operate the plurality of subpixels SP can include driving elements, lines, and the like. For example, the drive circuit can include a thin-film transistor, a storage capacitor, a gate line, a data line, and the like. However, the present disclosure is not limited thereto.

The non-display area is an area in which no image is displayed. The non-display area can refer to an outer peripheral portion of the display panel PN that surrounds the display area AA. The non-display area can overlap a black matrix. Various lines and circuits for operating the organic light-emitting element in the display area AA are disposed in the non-display area. For example, the non-display area can include link lines for transmitting signals to the plurality of subpixels SP and the drive circuit in the display area AA. The non-display area can include a drive integrated circuit (IC) D-IC such as a gate driver IC and a data driver IC. However, the present disclosure is not limited thereto.

The non-display area includes a first non-display area NA1, a bending area BA, and a second non-display area NA2.

The first non-display area NA1 is an area extending from the display area AA while surrounding the display area AA. The bending area BA can be an area extending from one side of the first non-display area NA1 and bent. The second non-display area NA2 can be an area extending from the bending area BA and disposed below the display area.

Meanwhile, with reference to FIG. 1A, the first non-display area NA1 and the second non-display area NA2 can be areas disposed on the same plane as the display area AA or disposed in parallel with the display area AA and kept in a flat state. For example, the first non-display area NA1 can be disposed flat on the same plane as the display area AA, and the second non-display area NA2 can be disposed flat below the display area AA and disposed in parallel with the display area AA. Therefore, for example, the display area AA, the first non-display area NA1, and the second non-display area NA2 can be referred to as non-bending areas. However, the present disclosure is not limited thereto.

With reference to FIG. 1A, the drive IC D-IC is disposed in the second non-display area NA2. The drive IC D-IC can provide data signals to the plurality of subpixels SP. For example, in response to the data timing control signal supplied from a timing controller, the drive IC D-IC can sample and latch a data signal supplied from the timing controller, convert the data signal into a gamma reference voltage, and output the gamma reference voltage. The drive IC D-IC can output the data signals through a plurality of data lines. For example, a pad part can be disposed in the second non-display area NA2 in which the drive IC D-IC is disposed, and a printed circuit board electrically connected to the pad part can be further disposed and provide a signal to the drive IC D-IC. However, the present disclosure is not limited thereto.

Meanwhile, the drive IC D-IC can be disposed in the form of a chip-on panel (COP) at one side of the display panel PN and connected to the display panel PN. Alternatively, the drive IC D-IC can be provided in the form of a chip-on film (COF) disposed on a separate flexible film and connected to the display panel PN. In a display device 100 according to the embodiment of the present disclosure, it is assumed that the drive IC D-IC is disposed in a COP shape. However, the present disclosure is not limited thereto.

In this case, as the display panel PN is bent, the drive IC D-IC disposed in the second non-display area NA2 can be disposed below the display area AA. For example, the drive IC D-IC and the printed circuit board, which is connected to the pad part of the display panel PN, can move to a rear surface side of the display panel PN and overlap the display area AA. Therefore, the circuit elements, such as the drive IC D-IC and the printed circuit board, may not be visually recognized when viewed from above the display panel PN. Therefore, a size of the non-display area, which is visually recognized from above the display panel PN, can be reduced, such that a narrow bezel can be implemented.

With reference to FIGS. 1A and 1D, through-holes TH are disposed in the display area AA. For example, an area in which the through-holes TH are disposed in the display area AA can be an area in which no image is displayed. The through-hole TH can be a hole formed through the display panel PN. The through-hole TH can be formed to correspond to a camera or an optical sensor. Therefore, the through-hole TH can be disposed in the display area AA of the display panel PN, thereby reducing a bezel area, which is the non-display area, and maximizing the display area AA. A design product with the maximized display area AA maximizes a degree of screen immersion of a user, thereby improving an aesthetic appearance.

The through-hole TH can be formed to correspond to an optical electronic device such as a camera or optical sensor. FIGS. 1A and 1D illustrate two through-holes TH. However, the present disclosure is not limited thereto. The number of through-holes TH can be variously provided. For example, one or two holes are disposed in the display area AA. A camera can be disposed in a first hole, and a distance detection sensor, a face recognition sensor, or a wide angle camera can be disposed in a second hole.

With reference to FIGS. 1A to 1D, a plurality of crack detection lines CDL configured to surround at least a part of the display area AA are disposed in the non-display area, and a plurality of pads PAD respectively connected to the plurality of crack detection lines CDL are disposed in the non-display area.

The plurality of pads PAD is disposed at one side of the second non-display area NA2. For example, the plurality of pads PAD can be disposed at an upper end of the second non-display area NA2. However, the present disclosure is not limited thereto. An area of the second non-display area NA2 in which the plurality of pads PAD is disposed can be referred to as a pad part. Meanwhile, FIG. 1A illustrates only the plurality of pads PAD connected to the plurality of crack detection lines CDL. However, the pad part can further include various pads to which drive voltages, data signals, or the like are inputted.

A detection part can be connected to the plurality of pads PAD. The detection part can detect whether a crack occurs by measuring resistance of the plurality of pads PAD connected to the plurality of crack detection lines CDL. For example, the detection part can input a detection signal to the pad PAD connected to one end of one crack detection line CDL and output a detection signal to the pad PAD connected to the other end of the corresponding crack detection line CDL. In this case, the detection part can include a circuit configured to measure resistance of the plurality of crack detection lines CDL by comparing a voltage value of the inputted detection signal and a voltage value of the outputted detection signal. Therefore, the detection part can detect a change in resistance of the plurality of crack detection lines CDL by comparing the inputted detection signal and the outputted detection signal and detect a crack of the plurality of crack detection lines CDL. However, the crack detection method is not limited thereto.

Meanwhile, the detection part connected to the plurality of crack detection lines CDL and the plurality of pads PAD can be connected to the drive IC D-IC. Therefore, the detection part can be configured to receive a crack detection signal through the drive IC D-IC or transmit a crack detection signal to the drive IC D-IC. However, the present disclosure is not limited thereto.

The plurality of crack detection lines CDL can extend from the plurality of pads PAD disposed in the second non-display area NA2 to the bending area BA and the first non-display area NA1. The plurality of crack detection lines CDL can be disposed in the first non-display area NA1 and surround at least a part of the display area AA.

The plurality of crack detection lines CDL include a lower detection line CDLa and an upper detection line CDLb. The lower detection line CDLa and the upper detection line CDLb can be disposed on different layers. For example, the lower detection line CDLa can be disposed below the upper detection line CDLb.

With reference to FIG. 1B, the lower detection line CDLa can be disposed at an outermost periphery of the first non-display area NA1 and detect whether a crack occurs in the display device 100. For example, the lower detection line CDLa can be a crack detection line for detecting a crack in an area adjacent to a substrate to be described below among the constituent elements of the display panel PN. Therefore, the lower detection line CDLa can be referred to as a panel crack detector (PCD). However, the present disclosure is not limited thereto. For example, the lower detection line CDLa can be formed on the same layer as some of the components of the thin-film transistors positioned in the display device 100.

The upper detection line CDLb can be disposed at the outermost periphery of the first non-display area NA1 and disposed inward of the lower detection line CDLa. For example, the upper detection line CDLb can be a crack detection line for detecting a crack in an area adjacent to an encapsulation part and a touch detection part to be described below among the constituent elements of the display panel PN and detecting noise caused by static electricity. Therefore, the upper detection line CDLb can be referred to as an encapsulation crack detector (ECD). However, the present disclosure is not limited thereto.

With reference to FIGS. 1A and 1B, one end and the other end of the lower detection line CDLa are connected to different pads PAD, and one end and the other end of the upper detection line CDLb are connected to different pads PAD. An area between one end and the other end of the lower detection line CDLa and an area between one end and the other end of the upper detection line CDLb are disposed along an outer periphery of the first non-display area NA1. For example, the lower detection line CDLa and the upper detection line CDLb can each extend from any one pad PAD to another pad PAD while being disposed along a periphery of the display panel PN.

An area between one end of the upper detection line CDLb and the other end of the upper detection line CDLb can be divided into a plurality of portions. For example, the upper detection line CDLb can include a first upper detection line CDLb1 and a second upper detection line CDLb2 connected in parallel. For example, as illustrated in FIG. 1B, the upper detection line CDLb can be disposed as one line in the second non-display area NA2 and the bending area BA and divided into the first upper detection line CDLb1 and the second upper detection line CDLb2 in the first non-display area NA1. However, the present disclosure is not limited thereto.

The first upper detection line CDLb1 and the second upper detection line CDLb2 can be spaced apart from each other at a predetermined interval and disposed in parallel with each other to surround the display area AA. With reference to FIG. 1B, the first upper detection line CDLb1 can be disposed in the display panel PN and disposed inward of the second upper detection line CDLb2.

Since the upper detection line CDLb includes the first upper detection line CDLb1 and the second upper detection line CDLb2 connected in parallel, the upper detection line CDLb can have a predetermined resistance value and detect whether a crack occurs even though any one of the first upper detection line CDLb1 and the second upper detection line CDLb2 is disconnected.

With reference to FIG. 1C, an area between one end of the lower detection line CDLa and the other end of the lower detection line CDLa can be divided into a plurality of portions. For example, the lower detection line CDLa can include a first lower detection line CDLa1 and a second lower detection line CDLa2 connected in parallel. For example, as illustrated in FIG. 1C, the lower detection line CDLa can be disposed as one line in the second non-display area NA2 and the bending area BA and divided into the first lower detection line CDLa1 and the second lower detection line CDLa2 in the first non-display area NA1. However, the present disclosure is not limited thereto.

The first lower detection line CDLa1 and the second lower detection line CDLa2 can be spaced apart from each other at a predetermined interval and disposed in parallel with each other to surround the display area AA. With reference to FIG. 1C, the first lower detection line CDLa1 can be disposed in the display panel PN and disposed inward of the second lower detection line CDLa2.

Since the lower detection line CDLa includes the first lower detection line CDLa1 and the second lower detection line CDLa2 connected in parallel, the lower detection line CDLa can have a predetermined resistance value and detect whether a crack occurs even though any one of the first lower detection line CDLa1 and the second lower detection line CDLa2 is disconnected.

Meanwhile, FIGS. 1B and 1C illustrate that the lower detection line CDLa and the upper detection line CDLb are each divided into two lines. However, the present disclosure is not limited thereto. For example, the lower detection line CDLa and the upper detection line CDLb can each be divided into three lines or configured only as one line without being divided.

With reference to FIG. 1D, the upper detection line CDLb is disposed to surround the through-hole TH. For example, the first upper detection line CDLb1 between the first upper detection line CDLb1 and the second upper detection line CDLb2 can be disposed on a peripheral portion of the through-hole TH. The first upper detection line CDLb1 extends from the first non-display area NA1 to the display area AA in which the through-holes TH are disposed. Further, the first upper detection line CDLb1 can extend from the display area AA, pass through the outer peripheries of the through-holes TH, and extend back to the first non-display area NA1. Therefore, the first upper detection line CDLb1 can be configured to detect the occurrence of a crack in the peripheral portion of the through-hole TH.

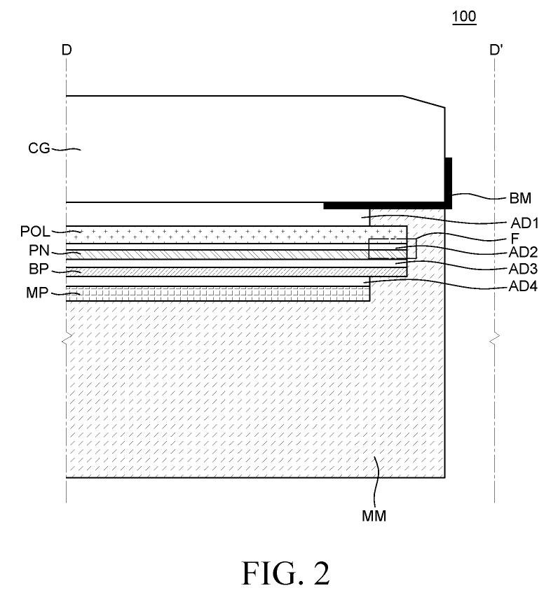

FIG. 2 is a cross-sectional view taken along line D-D' in FIG. 1A and is a cross-sectional view of the display device 100 according to the embodiment of the present disclosure. FIG. 2 illustrates only the display panel PN, a cover window CG, a backplate BP, a metal plate MP, and a molding member MM among various constituent elements of the display device 100.

With reference to FIG. 2, the display device 100 according to the present disclosure includes the display panel PN, the cover window CG, the backplate BP, the metal plate MP, and the molding member MM.

The cover window CG is disposed on a front surface of the display panel PN. The cover window CG can be a constituent element exposed from an outer periphery of the display device 100. The cover window CG protects the display device 100 from external impact and scratches. In addition, the cover window CG can protect the display device 100 from moisture or the like that permeates from the outside. The cover window CG can be made of glass or a plastic material having flexibility. However, the present disclosure is not limited thereto.

A black matrix BM is disposed below the cover window CG. The black matrix BM can be disposed at an outer periphery of the cover window CG and disposed along a periphery of the cover window CG. In this case, an area in which the black matrix BM is disposed can correspond to the first non-display area NA1. The black matrix BM can be made of a material with low permeability. Therefore, the black matrix BM can inhibit various constituent elements, which are disposed below the first non-display area NA1, from being visually recognized from the outside. In addition, the black matrix BM can be made of a material with conductivity and discharge static electricity of the cover window CG.

The black matrix BM can be made of resin containing chromium (Cr), graphite, or conductive particles. In this case, the resin can be one or more materials among acrylic resin, epoxy resin, phenolic resin, polyamide-based resin, polyimide-based resin, unsaturated polyester-based resin, polyphenylene-based resin, polyphenylene sulfide-based resin, and benzocyclobutene. However, the present disclosure is not limited thereto. In addition, the conductive particle can be made of any one of alloys of molybdenum (Mo), chromium (Cr), titanium (Ti), nickel (Ni), neodymium (Nd), copper (Cu), silver (Ag), and magnesium (Mg). However, the present disclosure is not limited thereto.

A polarizing plate POL is disposed between the display panel PN and the cover window CG. The polarizing plate POL is disposed on the front surface of the display panel PN. The polarizing plate POL can selectively transmit light and reduce reflection of external light entering the display panel PN. Specifically, the display panel PN includes various metallic materials applied to semiconductor elements, lines, organic light-emitting elements, and the like. Therefore, the external light entering the display panel PN can be reflected by the metallic material. The reflection of external light can decrease visibility of the display device 100. In contrast, in case that the polarizing plate POL is disposed, the polarizing plate POL can suppress the reflection of external light, thereby improving outdoor visibility of the display device 100. However, the polarizing plate POL can be excluded in accordance with the implementation of the display device 100. However, the present disclosure is not limited thereto.

A first bonding layer AD1 is disposed between the polarizing plate POL and the cover window CG, and a second bonding layer AD2 is disposed between the polarizing plate POL and the display panel PN. The first bonding layer AD1 can bond the cover window CG and the polarizing plate POL, and the second bonding layer AD2 can bond the polarizing plate POL and the display panel PN. As a result, the first bonding layer AD1 and the second bonding layer AD2 can bond the display panel PN and the cover window CG. The first bonding layer AD1 and the second bonding layer AD2 can each be configured as a transparent bonding layer so that an image of the display panel PN can be visually recognized. For example, the first bonding layer AD1 and the second bonding layer AD2 can each be made of optical clear adhesive (OCA). However, the present disclosure is not limited thereto.

The backplate BP is disposed below the display panel PN. The backplate BP can be disposed to support the display panel PN. For example, in case that the substrate of the display panel PN is made of a plastic material such as polyimide, a separate constituent element for protecting the substrate can be required because of the flexibility of the substrate. Therefore, a support substrate made of glass can be disposed below the substrate, and then a process of manufacturing the display device 100 can be performed. After the manufacturing process is completed, the support substrate can be separated and released. However, because a constituent element for supporting the substrate is required even after the support substrate is released, the backplate BP for supporting the substrate can be disposed below the display panel PN.

The backplate BP can include a plastic material. For example, the backplate BP can be configured as a thin plastic film made of polyimide (PI), polyethylene naphthalate (PEN), polyethylene terephthalate (PET), or a combination of these polymers.

A third bonding layer AD3 is disposed between the display panel PN and the backplate BP. The third bonding layer AD3 can bond the display panel PN and the backplate BP. The third bonding layer AD3 can be made of pressure-sensitive adhesive (PSA). However, the present disclosure is not limited thereto.

The metal plate MP is disposed below the backplate BP. The metal plate MP can protect the constituent elements of the display device 100 from external impact. In addition, the metal plate MP can serve as a ground to inhibit static electricity from permeating into the display device 100 and easily discharge residual charges, which are accumulated in the display device 100, to the outside. In addition, the metal plate MP can easily dissipate heat, which is generated from the display device 100, to the outside. The metal plate MP can be made of a metallic material excellent in thermal conductivity, electrical conductivity, and mechanical rigidity. For example, the metal plate MP can be made of copper (Cu) or stainless steel (SUS). However, the present disclosure is not limited thereto.

A fourth bonding layer AD4 is disposed between the backplate BP and the metal plate MP. The fourth bonding layer AD4 can bond the backplate BP and the metal plate MP. The fourth bonding layer AD4 can be made of pressure-sensitive adhesive (PSA). However, the present disclosure is not limited thereto.

The molding member MM seals the cover window CG, the display panel PN, the backplate BP, and the metal plate MP. Specifically, the molding member MM can be disposed to partially surround a lower portion of the cover window CG, a side surface of the display panel PN, a side surface of the backplate BP, and a side surface and a bottom surface of the metal plate MP. The molding member MM can inhibit moisture or oxygen from permeating into the display device 100. In addition, the molding member MM can protect the constituent elements of the display device 100 and mitigate an impact to be applied to the display device 100.

For example, the molding member MM can be formed by a process of filling a mold, which is disposed to surround the side surface of the cover window CG and disposed to partially expose the side surface of the display panel PN, the side surface of the backplate BP, the side surface and the bottom surface of the metal plate MP, with a material for forming the molding member MM, curing the material, and then removing the mold. However, the method of forming the molding member MM is not limited thereto.

For example, the molding member MM can be made of one or more materials among acrylic resin, epoxy resin, phenolic resin, polyamide-based resin, polyimide-based resin, unsaturated polyester-based resin, polyphenylene-based resin, polyphenylene sulfide-based resin, and benzocyclobutene. However, the present disclosure is not limited thereto.

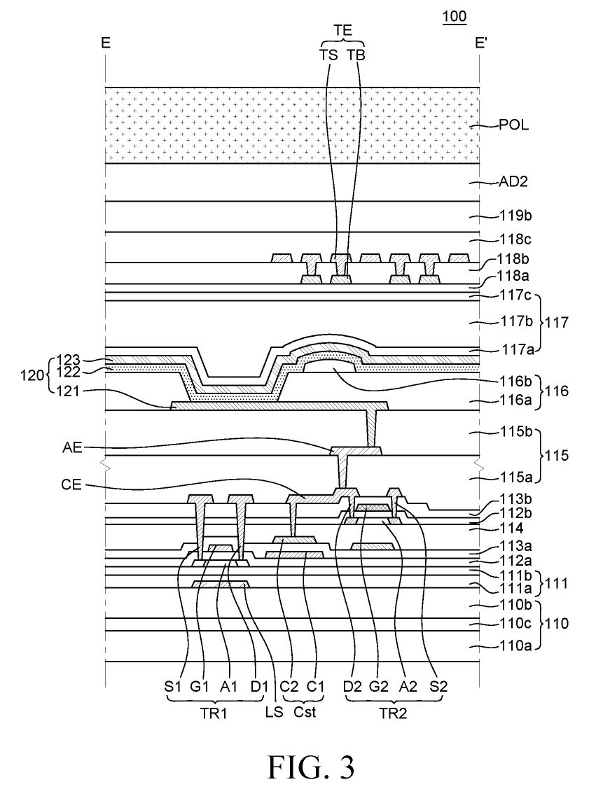

Hereinafter, a cross-sectional structure of the display area AA of the display panel PN will be described with reference to FIG. 3.

FIG. 3 is a cross-sectional view taken along line E-E' in FIG. 1A and is a cross-sectional view illustrating a cross-sectional structure of one subpixel SP disposed in the display area AA according to the embodiment of the present disclosure.

With reference to FIG. 3, a substrate 110, a light-blocking layer LS, a first buffer layer 111, a first thin-film transistor TR1, a second thin-film transistor TR2, a first gate insulation layer 112a, a first interlayer insulation layer 113a, a second buffer layer 114, a second gate insulation layer 112b, a second interlayer insulation layer 113b, a connection electrode CE, a first planarization layer 115a, a second planarization layer 115b, an auxiliary electrode AE, a bank 116a, a spacer 116b, a light-emitting element 120, an encapsulation part 117, a touch buffer layer 118a, a touch detection layer, a touch interlayer insulation layer 118b, a touch insulation layer 118c, a third planarization layer 119, the second bonding layer AD2, and the polarizing plate POL are disposed in the display area AA of the display panel PN in the display device 100 according to the embodiment of the present disclosure.

The substrate 110 serves to support and protect constituent elements of the display device 100 that are disposed above the substrate 110.

The substrate 110 is a component for supporting various constituent elements included in the display device 100 and can be made of an insulating material. Meanwhile, because the substrate 110 is disposed on a lowermost portion of the display device 100 and supports the constituent elements, the substrate 110 can be referred to as a lower substrate. However, the present disclosure is not limited thereto.

The substrate 110 can include a first substrate 110a, a second substrate 110b, and an interlayer insulation film 110c. The interlayer insulation film 110c can be disposed between the first substrate 110a and the second substrate 110b. As described above, the substrate 110 is configured by the first substrate 110a, the second substrate 110b, and the interlayer insulation film 110c, which can suppress moisture permeation. However, the substrate 110 can be disposed as a single layer. However, the present disclosure is not limited thereto.

For example, the first substrate 110a and the second substrate 110b can each be a polyimide (PI) substrate, and the interlayer insulation film 110c can be configured as a single layer made of silicon nitride (SiNx) or silicon oxide (SiOx) or a multilayer including the above-mentioned layers.

The interlayer insulation film 110c may not be disposed in at least a partial area. For example, the interlayer insulation film 110c may not be formed in an area, such as the bending area BA or an outermost peripheral area, in which stress is concentrated.

The light-blocking layer LS can be disposed on the substrate 110. The light-blocking layer LS is a protective layer disposed below semiconductor layers A1 and A2 of a plurality of transistors TR1 and TR2 in the display device 100 and made of metal for blocking external light. The light-blocking layer LS can minimize damage to the semiconductor layers A1 and A2 caused by external light.

The first buffer layer 111 can be disposed on the substrate 110 while covering the light-blocking layer LS. Specifically, a multi-buffer layer 111a can be disposed on the substrate 110 while covering the light-blocking layer LS, and an active buffer layer 111b can be disposed on the multi-buffer layer 111a.

The multi-buffer layer 111a can delay diffusion of moisture or oxygen having permeated into the substrate 110 and include at least any one of silicon nitride (SiNx) and silicon oxide (SiOx).

The active buffer layer 111b can protect the first semiconductor layer A1 and suppress various types of defects introduced from the substrate 110. For example, the active buffer layer 111b can include at least any one of amorphous silicon (a-Si), silicon nitride (SiNx), and silicon oxide (SiOx).

The first thin-film transistor TR1 can be disposed on the first buffer layer 111. The first thin-film transistor TR1 can include the first semiconductor layer A1, a first gate electrode G1, a first source electrode S1, and a first drain electrode D1. In this case, in accordance with design of a pixel circuit, the first source electrode S1 can be a first drain electrode, and the first drain electrode D1 can be a first source electrode.

The first semiconductor layer A1 can be disposed on the first buffer layer 111 so as to overlap the light-blocking layer LS. The first semiconductor layer A1 can include amorphous silicon or polysilicon (polycrystalline silicon). For example, the first semiconductor layer A1 can include low-temperature polysilicon (LTPS). For example, because a polysilicon material has high mobility (100 cm²/Vs or more), low energy power consumption, and excellent reliability, the polysilicon material can be applied to gate drivers and/or multiplexers (MUX) for driving elements for operating thin-film transistors for display elements. In the display device 100 according to the embodiment of the present disclosure, the polysilicon material can be applied to the first semiconductor layer A1 of the thin-film driving transistor. However, the present disclosure is not limited thereto. For example, the polysilicon material can also be applied to the second semiconductor layer A2 of the switching thin-film transistor in accordance with the properties of the display device 100. The first semiconductor layer A1 can be formed by depositing an amorphous silicon (a-Si) material on the first buffer layer 111, forming polysilicon by performing a dehydration process and a crystallization process, and then patterning the polysilicon.

In this case, the first semiconductor layer A1 can include a first channel area in which a channel is formed when the first thin-film transistor TR1 operates, and a first source area and a first drain area disposed at two opposite sides of the first channel area. The first source area refers to a portion of the first semiconductor layer A1 connected to the first source electrode S1, and the first drain area refers to a portion of the first semiconductor layer A1 connected to the first drain electrode D1. For example, the first source area and the first drain area can be configured by doping the first semiconductor layer A1 with ions (impurities). The first source area and the first drain area can be formed by doping the polysilicon material with ions. The first channel area can mean a portion in which the polysilicon material remains without being subjected to the ion doping.

The first gate insulation layer 112a can be disposed on the first semiconductor layer A1. The first gate insulation layer 112a can be configured as a single layer made of silicon nitride (SiNx) or silicon oxide (SiOx) or a multilayer including the above-mentioned layers. The first gate insulation layer 112a can have contact holes through which the first source electrode S1 and the first drain electrode D1 of the first thin-film transistor TR1 are respectively connected to the first source area and the first drain area of the first semiconductor layer A1 of the first thin-film transistor TR1.

The first gate electrode G1 of the first thin-film transistor TR1 and a first capacitor electrode C1 of a storage capacitor Cst can be disposed on the first gate insulation layer 112a.

In this case, the first gate electrode G1 and the first capacitor electrode C1 can each be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. The first gate electrode G1 can be formed on the first gate insulation layer 112a so as to overlap the first channel area of the first semiconductor layer A1 of the first thin-film transistor TR1.

The first capacitor electrode C1 can be excluded on the basis of the operating properties of the display device 100 and the structure, type, and the like of the thin-film transistor. The first gate electrode G1 and the first capacitor electrode C1 can be formed by the same process. Further, the first gate electrode G1 and the first capacitor electrode C1 can be made of the same material and formed on the same layer.

The first interlayer insulation layer 113a can be disposed above the first gate insulation layer 112a, the first gate electrode G1, and the first capacitor electrode C1. The first interlayer insulation layer 113a can be configured as a single layer made of silicon nitride (SiNx) or silicon oxide (SiOx) or a multilayer including the above-mentioned layers. Further, the first interlayer insulation layer 113a can have a contact hole through which the first source area and the first drain area of the first semiconductor layer A1 of the first thin-film transistor TR1 are exposed.

A second capacitor electrode C2 of the storage capacitor Cst can be disposed on the first interlayer insulation layer 113a. The second capacitor electrode C2 can be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof. The second capacitor electrode C2 can be formed on the first interlayer insulation layer 113a so as to overlap the first capacitor electrode C1. In addition, the second capacitor electrode C2 can be made of the same material as the first capacitor electrode C1. The second capacitor electrode C2 can be excluded on the basis of the operating properties of the display device 100 and the structure, type, and the like of the thin-film transistor.

The second buffer layer 114 can be disposed on the first interlayer insulation layer 113a and the second capacitor electrode C2. The second buffer layer 114 can be configured as a single layer made of silicon nitride (SiNx) or silicon oxide (SiOx) or a multilayer including the above-mentioned layers. The second buffer layer 114 can have a contact hole through which the first source area and the first drain area of the first semiconductor layer A1 of the first thin-film transistor TR1 are exposed. In addition, the second buffer layer 114 can have a contact hole through which the second capacitor electrode C2 of the storage capacitor Cst is exposed.

The second buffer layer 114 can be configured as a multilayer. However, the present disclosure is not limited thereto.

The second semiconductor layer A2 of the second thin-film transistor TR2 can be disposed on the second buffer layer 114. In this case, the second thin-film transistor TR2 can include the second semiconductor layer A2, the second gate insulation layer 112b, a second gate electrode G2, a second source electrode S2, and a second drain electrode D2. In this case, in accordance with design of the pixel circuit, the second source electrode S2 can be a drain electrode, and the second drain electrode D2 can be a source electrode.

In addition, the second semiconductor layer A2 can include a second channel area in which a channel is formed when the second thin-film transistor TR2 operates, and a second source area and a second drain area disposed at two opposite sides of the second channel area. The second source area can refer to a portion of the second semiconductor layer A2 connected to the second source electrode S2, and the second drain area can refer to a portion of the second semiconductor layer A2 connected to the second drain electrode D2.

The second semiconductor layer A2 can be made of an oxide semiconductor. The oxide semiconductor material is a material having a larger band gap than a silicon material and has a low off-current because electrons cannot pass through the band gap in an OFF state. Therefore, the thin-film transistor including the semiconductor layer made of the oxide semiconductor can be suitable for a switching thin-film transistor that maintains the short ON time and the long OFF time. However, the present disclosure is not limited thereto.

The thin-film transistor including the semiconductor layer made of oxide semiconductor can be applied as a thin-film driving transistor in accordance with the properties of the display device 100. Further, because the oxide semiconductor material has a low off-current and can decrease a magnitude of an auxiliary capacity, the oxide semiconductor material is suitable for a high-resolution display element. For example, the second semiconductor layer A2 can be made of a metal oxide, for example, various metal oxides such as indium-gallium-zinc oxide (IGZO). In this case, the description has been made on the assumption that the second semiconductor layer A2 of the second thin-film transistor TR2 is made of IGZO among various metal oxides. However, the present disclosure is not limited thereto. The second semiconductor layer A2 of the second thin-film transistor TR2 can be made of another metal oxide, such as indium-zinc oxide (IZO), indium-gallium-tin oxide (IGTO), or indium-gallium oxide (IGO), instead of IGZO.

The second semiconductor layer A2 can be formed by depositing a metal oxide on the second buffer layer 114, performing a heat treatment process for stabilization, and then patterning the metal oxide.

The second gate insulation layer 112b can be disposed on the entire substrate 110 including the second semiconductor layer A2. For example, the second gate insulation layer 112b can be configured as a single layer made of silicon nitride (SiNx) or silicon oxide (SiOx) or a multilayer including the above-mentioned layers.

The second gate electrode G2 can be disposed on the second gate insulation layer 112b.

The second gate electrode G2 can be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof.

For example, the second gate electrode G2 is formed by forming a metallic material on the second gate insulation layer 112b, forming a photoresist pattern on the metallic material, and then wet-etching the metallic material by using the photoresist pattern as a mask. A material, which selectively etches molybdenum (Mo), copper (Cu), titanium (Ti), aluminum (Al), chromium (Cr), gold (Au), nickel (Ni), and neodymium (Nd), or an alloy thereof, which constitutes the metallic material and does not etch the insulating material, can be used as a wet etching liquid for etching the metallic material.

The second interlayer insulation layer 113b can be disposed on the second gate insulation layer 112b and the second gate electrode G2. The second interlayer insulation layer 113b can have a contact hole through which the first semiconductor layer A1 of the first thin-film transistor TR1 and the second semiconductor layer A2 of the second thin-film transistor TR2 are exposed. For example, the second interlayer insulation layer 113b can have a contact hole through which the first source area and the first drain area of the first semiconductor layer A1 of the first thin-film transistor TR1 are exposed. The second interlayer insulation layer 113b can have a contact hole through which the second source area and the second drain area of the second semiconductor layer A2 of the second thin-film transistor TR2 are exposed.

The second interlayer insulation layer 113b can be configured as a single layer made of silicon nitride (SiNx) or silicon oxide (SiOx) or a multilayer including the above-mentioned layers.

The connection electrode CE, the first source electrode S1 and the second drain electrode D1 of the first thin-film transistor TR1, and the second source electrode S2 and the second drain electrode D2 of the second thin-film transistor TR2 can be disposed on the second interlayer insulation layer 113b.

The connection electrode CE can be electrically connected to the second drain electrode D2 of the second thin-film transistor TR2. Further, the connection electrode CE can be electrically connected to the second capacitor electrode C2 of the storage capacitor Cst through contact holes formed in the second buffer layer 114 and the second interlayer insulation layer 113b. For example, the connection electrode CE can serve to electrically connect the second capacitor electrode C2 of the storage capacitor Cst and the second drain electrode D2 of the second thin-film transistor TR2.

In this case, the first source electrode S1 and the first drain electrode D1 of the first thin-film transistor TR1 can be connected to the first semiconductor layer A1 of the first thin-film transistor TR1 through contact holes formed in the first gate insulation layer 112a, the first interlayer insulation layer 113a, the second buffer layer 114, and the second interlayer insulation layer 113b.

The second source electrode S2 and the second drain electrode D2 of the second thin-film transistor TR2 can be connected to the second semiconductor layer A2 through a contact hole formed in the second interlayer insulation layer 112b.

The connection electrode CE, the first source electrode S1 and the first drain electrode D1 of the first thin-film transistor TR1, and the second source electrode S2 and the second drain electrode D2 of the second thin-film transistor TR2 can be formed by the same process and made of the same material.

For example, the connection electrode CE, the first source electrode S1 and the first drain electrode D1 of the first thin-film transistor TR1, and the second source electrode S2 and the second drain electrode D2 of the second thin-film transistor TR2 can each configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. For example, the connection electrode CE, the first source electrode S1 and the first drain electrode D1 of the first thin-film transistor TR1, and the second source electrode S2 and the second drain electrode D2 of the second thin-film transistor TR2 can each have a three-layer structure including titanium (Ti)/aluminum (Al)/titanium (Ti). However, the present disclosure is not limited thereto.

The connection electrode CE can be integrally connected to the second drain electrode D2 of the second thin-film transistor TR2. However, the present disclosure is not limited thereto.

The first planarization layer 115a can be disposed above the connection electrode CE, the first source electrode S1 and the first drain electrode D1 of the first thin-film transistor TR1, the second source electrode S2 and the second drain electrode D2 of the second thin-film transistor TR2, and the second interlayer insulation layer 113b.

The first planarization layer 115a can be an organic layer for planarizing and protecting an upper portion of the first thin-film transistor TR1 and an upper portion of the second thin-film transistor TR2. For example, the first planarization layer 115a can be made of an organic material such as acrylic resin, epoxy resin, phenolic resin, polyamide resin, and polyimide resin.

The auxiliary electrode AE can be disposed on the first planarization layer 115a. The auxiliary electrode AE can be connected to the second drain electrode D2 of the second thin-film transistor TR2 through a contact hole of the first planarization layer 115a. The auxiliary electrode AE can serve to electrically connect the second thin-film transistor TR2 and a first electrode 121. Further, the auxiliary electrode AE can be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof. The auxiliary electrode AE can be made of the same material as the second source electrode S2 and the second drain electrode D2 of the second thin-film transistor TR2.

The second planarization layer 115b can be disposed above the auxiliary electrode AE and the first planarization layer 115a. For example, the second planarization layer 115b can be made of an organic material such as acrylic resin, epoxy resin, phenolic resin, polyamide resin, and polyimide resin.

The light-emitting element 120 can be disposed on the second planarization layer 115b. The light-emitting element 120 includes an anode 121, a light-emitting layer 122, and a cathode 123.

The anode 121 can be disposed on the second planarization layer 115b. In this case, the anode 121 can be electrically connected to the auxiliary electrode AE through a contact hole provided in the second planarization layer 115b. The anode 121 can be made of a metallic material.

In case that the display device 100 is a top-emission type display device in which light emitted from the light-emitting element 120 propagates toward an upper side of the substrate 110 on which the light-emitting element 120 is disposed, the anode 121 can include a reflective layer, and a transparent conductive layer disposed on the reflective layer. For example, the transparent conductive layer can be made of transparent conductive oxide such as indium tin oxide (ITO) or indium zinc oxide (IZO). For example, the transparent conductive layer can be made of silver (Ag), aluminum (Al), gold (Au), molybdenum (Mo), tungsten (W), chromium (Cr), or an alloy thereof. However, the present disclosure is not limited thereto.

A bank part 116 is disposed on the anode 121. The bank part 116 includes the bank 116a and the spacer 116b.

The bank 116a can be disposed while covering an end of the anode 121. A portion of the bank 116a, which corresponds to the light-emitting area of the subpixel, can be opened. A part of the anode 121 can be exposed through the opened portion (hereinafter, referred to as an open area) of the bank 116a. In this case, the bank 116a can be made of an inorganic insulating material such as silicon nitride (SiNx) or silicon oxide (SiOx), or an organic insulating material such as benzocyclobutene-based resin, acrylic resin, or imide-based resin. However, the present disclosure is not limited thereto.

The spacer 116b can be further disposed on the bank 116a. The spacer 116b serves to maintain a predetermined gap so that a mask does not come into contact with the substrate during a process of manufacturing the light-emitting layer 122 made of an organic material in the light-emitting element 120.

For example, the spacer 116b can be made of an inorganic insulating material such as silicon nitride (SiNx) or silicon oxide (SiOx), or an organic insulating material such as benzocyclobutene-based resin, acrylic resin, or imide-based resin. However, the present disclosure is not limited thereto.

The light-emitting layer 122 is disposed on the anode 121, the bank 116a, and the spacer 116b. The light-emitting layer 122 can be disposed in the open area of the bank 116a and an area at the periphery of the open area. Therefore, the light-emitting layer 122 can be disposed on the anode 121 exposed through the open area of the bank 116.

The light-emitting layer 122 can include a plurality of organic material layers. For example, the light-emitting layer 122 can include organic material layers such as a hole injection layer, a hole transport layer, an electron transport layer, and an electron injection layer. Meanwhile, in case that the light-emitting layer 122 is the light-emitting layer 122 configured to emit white light, the light beam emitted from the light-emitting layer 122 can be converted into light beams with various colors by a plurality of color filters CF. However, the present disclosure is not limited thereto.

The cathode 123 is disposed on the light-emitting layer 122. Because the cathode 123 supplies electrons to the light-emitting layer 122, the cathode 123 can be made of an electrically conductive material having a low work function. The cathode 123 can be configured as a single layer over the plurality of subpixels SP. For example, the cathodes 123 of the plurality of subpixels SP can be connected to and integrated with one another.

For example, the cathode 123 can be made of an electrically transparent conductive material such as indium tin oxide (ITO) or indium zinc oxide (IZO) or made of an alloy of ytterbium (Yb). The cathode 123 can further include a metal doping layer. However, the present disclosure is not limited thereto.

The encapsulation part 117 is disposed on the light-emitting element 120.

The encapsulation part 117 can have a single-layer structure or a multilayer structure. For example, the encapsulation part 117 can have a multilayer structure including a first encapsulation layer 117a, a second encapsulation layer 117b, and a third encapsulation layer 117c. However, the encapsulation part can have a single layer structure. However, the present disclosure is not limited thereto.

The first encapsulation layer 117a and the third encapsulation layer 117c can be made of an inorganic material, and the second encapsulation layer 117b can be made of an organic material. The second encapsulation layer 117b can be thickest among the first encapsulation layer 117a, the second encapsulation layer 117b, and the third encapsulation layer 117c. The second encapsulation layer 117b can planarize an upper portion of the light-emitting element 120.

The first encapsulation layer 117a can be disposed on the cathode 123 and configured to be closest to the light-emitting element 120 among the layers of the encapsulation part. For example, the first encapsulation layer 117a can be made of silicon nitride (SiNx), silicon oxide (SiOx), silicon oxynitride (SiON), aluminum oxide (Al₂O₃), or the like. However, the present disclosure is not limited thereto.

The second encapsulation layer 117b can have a smaller area than the first encapsulation layer 117a. In this case, the second encapsulation layer 117b can be formed to expose two opposite ends of the first encapsulation layer 117a. The second encapsulation layer 117b can serve as a buffer for mitigating stress between the layers caused when the flexible display device is bent. The second encapsulation layer 117b can serve to improve the planarization function.

For example, the second encapsulation layer 117b can be made of an organic insulating material such as acrylic resin, epoxy resin, polyimide, polyethylene, or silicon oxycarbon (SiOC). For example, the second encapsulation layer 117b can also be formed in an inkjet manner. However, the present disclosure is not limited thereto.

The third encapsulation layer 117c can be formed above the substrate 110 having the second encapsulation layer 117b to cover a top surface and a side surface of each of the second encapsulation layer 117b and the first encapsulation layer 117a. In this case, the third encapsulation layer 117c can minimize or block the permeation of outside moisture or oxygen into the first encapsulation layer 117a and the second encapsulation layer 117b. For example, the third encapsulation layer 117c can be made of an inorganic insulating material such as silicon nitride (SiNx), silicon oxide (SiOx), silicon oxynitride (SiON), or aluminum oxide (Al₂O₃). However, the present disclosure is not limited thereto.

The touch detection layer can be disposed on the encapsulation part 117.

The touch detection layer can include the touch buffer layer 118a, the touch interlayer insulation layer 118b, touch electrodes TE, and the touch insulation layer 118c. The touch electrode TE can include a touch sensor electrode TS and a touch bridge electrode TB positioned on different layers.

For example, the touch buffer layer 118a can be disposed on the third encapsulation layer 117c, and the touch bridge electrode TB can be disposed on the touch buffer layer 118a.

The touch interlayer insulation layer 118b can be disposed on the touch bridge electrode TB, and the touch sensor electrode TS can be disposed on the touch interlayer insulation layer 118b.

The touch insulation layer 118c is disposed on the touch sensor electrode TS. The touch insulation layer 118c can be an organic layer for planarizing and protecting an upper portion of the touch sensor electrode TS. Therefore, the touch insulation layer 118c can be disposed to adjoin the touch sensor electrode TS. For example, the touch insulation layer 118c can be made of an organic material such as acrylic resin, epoxy resin, phenolic resin, polyamide resin, and polyimide resin. However, the present disclosure is not limited thereto. For example, the touch buffer layer 118a, the touch interlayer insulation layer 118b, and the touch insulation layer 118c can each be made of an inorganic insulating material or an organic insulating material. Therefore, the touch buffer layer 118a, the touch interlayer insulation layer 118b, and the touch insulation layer 118c can each minimize a level difference at a point at which the touch electrode TE is disposed. The touch buffer layer 118a, the touch interlayer insulation layer 118b, and the touch insulation layer 118c can each electrically insulate the touch sensor electrode TS and the touch bridge electrode TB.

The third planarization layer 119b is disposed on the touch insulation layer 118c. The third planarization layer 119b can planarize upper portions of the plurality of touch electrodes TE. In particular, the third planarization layer 119b can be configured to entirely planarize upper portions of the display area AA, the first non-display area NA1, and the second non-display area NA2 on the substrate 110. Therefore, the third planarization layer 119b can be configured to be disposed on an uppermost layer on the display panel PN. However, the present disclosure is not limited thereto. The third planarization layer 119b can be made of an organic material, e.g., epoxy-based resin or the like. However, the present disclosure is not limited thereto.

Meanwhile, with reference to FIG. 3, the second bonding layer AD2 and the polarizing plate POL can be disposed on the third planarization layer 119b. The second bonding layer AD2 can be disposed to adjoin a top surface of the third planarization layer 119b and a bottom surface of the polarizing plate POL and configured to bond the third planarization layer 119b and the polarizing plate POL. However, the present disclosure is not limited thereto.

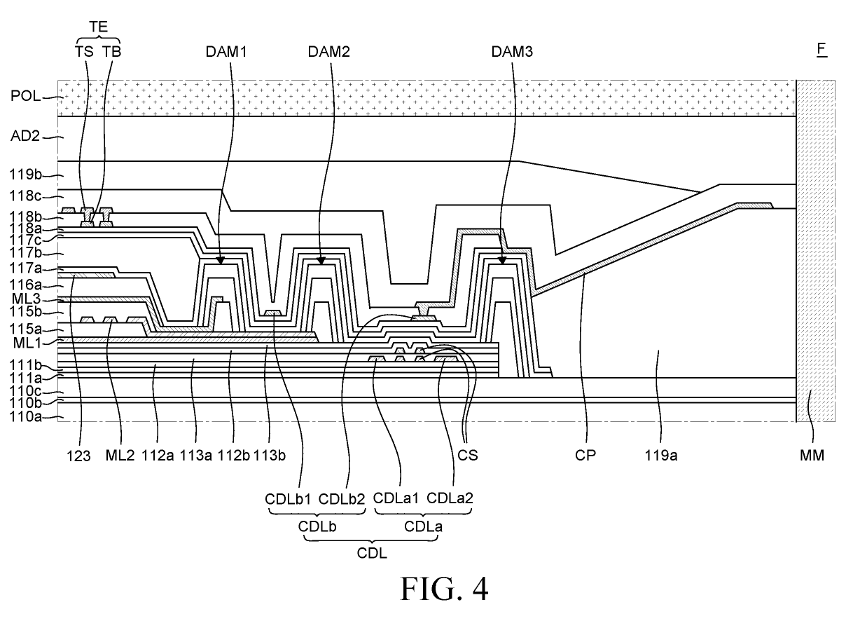

Hereinafter, a cross-sectional structure of the first non-display area NA1 of the display panel PN will be described with reference to FIG. 4.

FIG. 4 is an enlarged cross-sectional view of area F in FIG. 2, and is a cross-sectional view illustrating a cross-sectional structure of the first non-display area NA1 according to the embodiment of the present disclosure.

With reference to FIG. 4, a first metal layer ML1, a second metal layer ML2, a third metal layer ML3, the plurality of crack detection lines CDL, a plurality of crack stoppers CS, a first dam DAM1, a second dam DAM2, a third dam DAM3, a protective layer 119a, and a conductive pattern CP are disposed in the first non-display area NA1 of the display panel PN in the display device 100 according to the embodiment of the present disclosure.

The first metal layer ML1 is disposed in the first non-display area NA1 and disposed on the second interlayer insulation layer 113b. The first metal layer ML1 can be made of the same material as one of various conductive constituent elements formed in the display area AA. For example, the first metal layer ML1 can be formed on the second interlayer insulation layer 113b and formed by the same process and made of the same material as the source electrodes S1 and S2 and the drain electrodes D1 and D2. However, the present disclosure is not limited thereto.

For example, the first metal layer ML1 can be a low-potential power line. The first metal layer ML1 can be electrically connected to the cathode 123 through the second metal layer ML2 and the third metal layer ML3. Therefore, the first metal layer ML1 can supply a low-potential voltage to the cathode 123.

The second metal layer ML2 is disposed on the first metal layer ML1 and the first planarization layer 115a. The second metal layer ML2 can be disposed at the outermost periphery of the first non-display area NA1 and disposed along the periphery of the substrate 110. The second metal layer ML2 can be made of the same material as one of various conductive constituent elements formed in the display area AA. For example, the second metal layer ML2 can be formed on the first planarization layer 115a and formed by the same process and made of the same material as the auxiliary electrode AE. However, the present disclosure is not limited thereto.

The second metal layer ML2 can include a plurality of holes. Therefore, a gas, which is generated from the first planarization layer 115a or the second planarization layer 115b during the manufacturing process, can be easily discharged to the outside through the plurality of holes of the second metal layer ML2.

The third metal layer ML3 is disposed on the second metal layer ML2 and the second planarization layer 115b. The third metal layer ML3 extends onto the second metal layer ML2 and is disposed to adjoin the second metal layer ML2. The third metal layer ML3 can be made of the same material as one of various conductive constituent elements formed in the display area AA. The third metal layer ML3 can be formed by the same process and made of the same material as the anode 121. However, the present disclosure is not limited thereto.

The third metal layer ML3 is electrically connected to the cathode 123 in the first non-display area NA1. Therefore, the third metal layer ML3 can supply a low-potential voltage, which is supplied through the first metal layer ML1 and the second metal layer ML2, to the cathode 123.

A plurality of dams is disposed in an area adjacent to an end of the substrate 110 in the first non-display area NA1. The plurality of dams is each disposed in the first non-display area NA1 and surround the display area AA.

The plurality of dams can include the first dam DAM1, the second dam DAM2, and the third dam DAM3.

The first dam DAM1 and the second dam DAM2 can be disposed to overlap the first metal layer ML1 and the second metal layer ML2. However, the present disclosure is not limited thereto. The first dam DAM1 and the second dam DAM2 can be disposed adjacent to the display area AA and configured to inhibit the organic encapsulation layer 117b from being excessively applied.

The third dam DAM3 can be an outermost peripheral dam disposed at the outermost periphery of the display panel PN among the plurality of dams. The third dam DAM3 can cover ends of a plurality of inorganic insulation layers disposed in the first non-display area NA1. However, the present disclosure is not limited thereto.

The first dam DAM1, the second dam DAM2, and the third dam DAM3 can each have a structure in which a plurality of organic layers made of the same material as the constituent elements disposed in the display area AA are stacked. For example, the first dam DAM1, the second dam DAM2, and the third dam DAM3 can be formed by the same process and made of the same material as the second planarization layer 115b, the bank 116a, and the spacer 116b. However, the present disclosure is not limited thereto.

In addition, FIG. 4 illustrates that the plurality of dams is provided as three dams, i.e., the first dam DAM1, the second dam DAM2, and the third dam DAM3. However, the present disclosure is not limited thereto. The number of dams can be changed, as necessary.

The plurality of crack detection lines CDL is disposed in the first non-display area NA1. The plurality of crack detection lines CDL can be disposed inward of the third dam DAM3 that is the outermost peripheral dam.

Among the plurality of crack detection lines CDL, the lower detection line CDLa can be made of the same material as one of various conductive constituent elements formed in the display area AA. For example, the lower detection line CDLa can be formed on the first gate insulation layer 112a and formed by the same process and made of the same material as the first gate electrode G1. Therefore, the lower detection line CDLa can detect a crack occurring in the layers, such as the substrate 110, the first buffer layer 111, the first gate insulation layer 112a, the first interlayer insulation layer 113a, the second buffer layer 114, the second gate insulation layer 112b, and the second interlayer insulation layer 113b, adjacent to the lower detection line CDLa. However, the present disclosure is not limited thereto. The lower detection line CDLa can be formed by the same process as other conductive constituent elements other than the first gate electrode G1.

The lower detection line CDLa can include the first lower detection line CDLa1 and the second lower detection line CDLa2. The first lower detection line CDLa1 and the second lower detection line CDLa2 can be spaced apart from each other at a predetermined interval and disposed in parallel with each other. With reference to FIG. 4, the first lower detection line CDLa1 can be disposed inward of the second lower detection line CDLa2.

The plurality of crack stoppers CS are disposed between the first lower detection line CDLa1 and the second lower detection line CDLa2. The plurality of crack stoppers CS can be configured to increase lengths of the plurality of inorganic layers disposed in the first non-display area NA1 or to disconnect the plurality of inorganic layers. Therefore, the plurality of crack stoppers CS can minimize the propagation of a crack from the first non-display area NA1 to the display area AA through the plurality of inorganic layers.

For example, the plurality of crack stoppers CS can be formed by the same process and made of the same material as the first gate electrode G1 or the second capacitor electrode C2. However, the present disclosure is not limited thereto.

Among the plurality of crack detection lines CDL, the upper detection line CDLb can be made of the same material as one of various conductive constituent elements formed in the display area AA. For example, the upper detection line CDLb can be formed on the touch buffer layer 118a and formed by the same process and made of the same material as the touch bridge electrode TB. Therefore, the upper detection line CDLb can detect a crack occurring in the layers, such as the encapsulation part 117, the touch buffer layer 118a, and the touch interlayer insulation layer 118b, adjacent to the upper detection line CDLb. However, the present disclosure is not limited thereto. The upper detection line CDLb can be formed by the same process as other conductive constituent elements other than the encapsulation part 117, the touch buffer layer 118a, and the touch interlayer insulation layer 118b.

The upper detection line CDLb can include the first upper detection line CDLb1 and the second upper detection line CDLb2. The first upper detection line CDLb1 and the second upper detection line CDLb2 can be spaced apart from each other at a predetermined interval and disposed in parallel with each other. With reference to FIG. 4, the first upper detection line CDLb1 can be disposed inward of the second upper detection line CDLb2. For example, the first upper detection line CDLb1 can be disposed between the first dam DAM1 and the second dam DAM2, and the second upper detection line CDLb2 can be disposed between the second dam DAM2 and the third dam DAM3. However, the present disclosure is not limited thereto.

The protective layer 119a is disposed in the first non-display area NA1 and disposed outward of the third dam DAM3 that is the outermost peripheral dam. The protective layer 119a is disposed outward of the third dam DAM3 between the inside and outside of the third dam DAM3. The protective layer 119a is disposed between the third dam DAM3 and the end of the substrate 110. The protective layer 119a is disposed at the outermost periphery of the first non-display area NA1 and has an inclined surface inclined inward. For example, the protective layer 119a can be configured such that the third dam DAM3 minimizes a situation in which the protective layer 119a is excessively applied in the display area AA.

For example, the protective layer 119a can be made of an organic material such as acrylic resin, epoxy resin, phenolic resin, polyamide resin, and polyimide resin. However, the present disclosure is not limited thereto.

Meanwhile, breaking strength of the protective layer 119a can be higher than breaking strength of the third planarization layer 119b. For example, a Young's modulus of the protective layer 119a can be larger than a Young's modulus of the third planarization layer 119b. Therefore, the protective layer 119a can be configured to reinforce the strength of the third planarization layer 119b at the outermost periphery of the display panel PN. However, the present disclosure is not limited thereto.

The conductive pattern CP is disposed on the protective layer 119a. The conductive pattern CP is disposed along a part of a top surface and a part of a side surface of the third dam DAM3 and a top surface of the protective layer 119a. The conductive pattern CP can extend from the top surface of the protective layer 119a and be disposed to cover a part of the top surface and a part of the side surface of the third dam DAM3, such that the conductive pattern CP can extend inward from the third dam DAM3.

The conductive pattern CP is disposed inward of the third dam DAM3 and electrically connected to the crack detection line CDL. The conductive pattern CP can be electrically connected to the second upper detection line CDLb2 through a contact hole formed in the touch interlayer insulation layer 118b. Therefore, the conductive pattern CP can be configured to detect a crack in an upper area of the protective layer 119a and a crack at the outermost periphery of the substrate 110, thereby expanding a detection area of the second upper detection line CDLb2.

The conductive pattern CP can be made of the same material as one of various conductive constituent elements formed in the display area AA. For example, the conductive pattern CP can be formed on the touch interlayer insulation layer 118b and formed by the same process and made of the same material as the touch sensor electrode TS. However, the present disclosure is not limited thereto.

The touch insulation layer 118c is disposed on the plurality of touch electrodes TE and the conductive pattern CP. The touch insulation layer 118c can be disposed above the plurality of touch electrodes TE and extend to the top surfaces of the plurality of dams DAM1, DAM2, and DAM3 and the top surface of the conductive pattern CP. In this case, the touch insulation layer 118c disposed on the conductive pattern CP can be disposed to have a constant thickness. For example, the touch insulation layer 118c can be disposed on the conductive pattern CP and have a constant thickness.

The third planarization layer 119b, the second bonding layer AD2, and the polarizing plate POL can be disposed on the protective layer 119a and the touch insulation layer 118c. The third planarization layer 119b can be configured to planarize the upper portions of the protective layer 119a and the touch insulation layer 118c, thereby entirely planarizing the upper portions of the display area AA and the first non-display area NA1 on the substrate 110.

The molding member MM is disposed on lateral portions of the substrate 110, the protective layer 119a, the touch insulation layer 118c, the third planarization layer 119b, the second bonding layer AD2, and the polarizing plate POL. During the process of manufacturing the display device 100, a process of cutting a mother substrate can be performed by a process of trimming the side surface of the display panel PN. In this case, the molding member MM can surround the side surface of the display panel PN, which has been subjected to the trimming process, and inhibit moisture or oxygen from permeating into the display device 100.

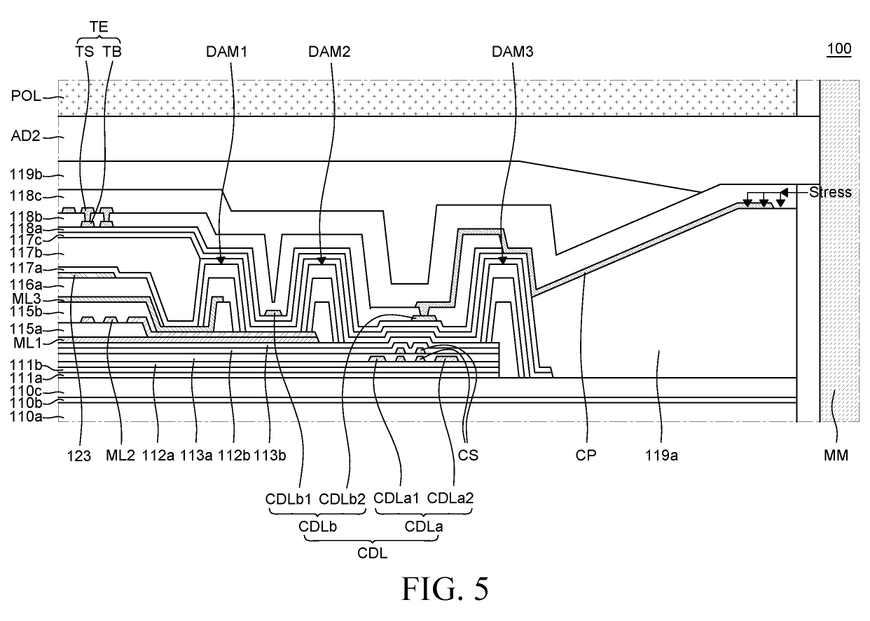

FIG. 5 is a cross-sectional view for explaining a case in which the display device according to one or more embodiments of the present disclosure partially contracts.

With reference to FIG. 5, in the display device 100 according to the embodiments of the present disclosure, the molding member MM can be disposed to be spaced apart from the lateral portion of the substrate 110, the lateral portion of the protective layer 119a, the lateral portion of the touch insulation layer 118c, the lateral portion of the third planarization layer 119b, and the lateral portion of the polarizing plate POL.

For example, the constituent elements, such as the protective layer 119a, the touch insulation layer 118c, and the third planarization layer 119b, made of an organic material can contract or expand in volume in a low-temperature or high-temperature environment. In contrast, because the second bonding layer AD2 is made of a material having adhesiveness, the second bonding layer AD2 can be bonded to the molding member MM even in a low-temperature or high-temperature environment. Therefore, stress caused by deformation can be concentrated on contact surfaces of the second bonding layer AD2, the protective layer 119a, the touch insulation layer 118c, and the third planarization layer 119b, which can cause a crack.

In contrast, the conductive pattern CP extending to the outermost periphery of the display panel PN is disposed on the protective layer 119a in the display device 100 according to the embodiment of the present disclosure. Therefore, the conductive pattern CP made of a rigid material, e.g., metal can be configured to reinforce rigidity of the protective layer 119a and the touch insulation layer 118c. Therefore, even though the protective layer 119a, the touch insulation layer 118c, and the third planarization layer 119b become spaced apart from the molding member MM while contracting, as illustrated in FIG. 5, the propagation of the crack occurring in the contact surface with the second bonding layer AD2 to the display area AA can be minimized.

The molding member, which is integrally formed and directly surrounds the components of the display device, can be disposed below the side surface of the display panel and the side surface of the cover window in the display device. Therefore, with the molding member, a separate component, such as a cover part for protecting the constituent elements of the display device, can be excluded, thereby providing an advantage of implementing a narrow bezel.

However, because the constituent element made of an organic material on the display panel can contract or expand in volume in a low-temperature or high-temperature environment, there can occur a defect in which the molding member is spaced apart from the constituent elements made of an organic material.

In addition, the adhesiveness of the material, such as a bonding layer, having adhesiveness can inhibit the constituent element made of an organic material from being spaced apart from the molding member even though the constituent element contracts. For this reason, stress is concentrated on a bonding surface of the organic material layer being in contact with the bonding layer, which causes a problem of the occurrence of a crack.

Meanwhile, in case that this crack propagates to the display area through the organic material layer, moisture can permeate into the display panel through the cracked portion. For this reason, there can occur a severe problem in that display quality of the display device deteriorates.

In the display device 100 according to the embodiments of the present disclosure, the protective layer 119a and the conductive pattern CP are disposed at the outermost periphery of the display panel PN, thereby minimizing contraction deformation of the third planarization layer 119b.

Specifically, in the display device 100 according to the embodiment of the present disclosure, the protective layer 119a is disposed outward of the third planarization layer 119b, and the conductive pattern CP extending to the outermost periphery of the display panel PN is disposed on the protective layer 119a. For example, the conductive pattern CP is made of a rigid material such as metal, such that the conductive pattern CP can be configured to reinforce rigidity of the protective layer 119a and the touch insulation layer 118c made of an organic material. Therefore, it is possible to minimize the concentration of stress caused by deformation by minimizing the deformation of the protective layer 119a and the touch insulation layer 118c. Therefore, in the display device 100 according to the embodiment of the present disclosure, the protective layer 119a and the conductive pattern CP are disposed at the outermost periphery of the display panel PN, thereby minimizing contraction deformation of the third planarization layer 119b and improving the reliability of the display device 100.

In the display device 100 according to the embodiments of the present disclosure, the protective layer 119a and the conductive pattern CP are disposed at the outermost periphery of the display panel PN, thereby minimizing a degree to which a crack occurring in the contact surface with the second bonding layer AD2 propagates to the display area AA. For example, the conductive pattern CP is made of a rigid material that causes no crack, such that the propagation of a crack can be blocked by the conductive pattern CP. Therefore, even though stress caused by deformation is concentrated on the contact surface with the second bonding layer AD2, the conductive pattern CP can be configured to minimize the propagation of a crack occurring in the contact surface with the second bonding layer AD2 to the display area AA, thereby improving the display quality of the display device 100.

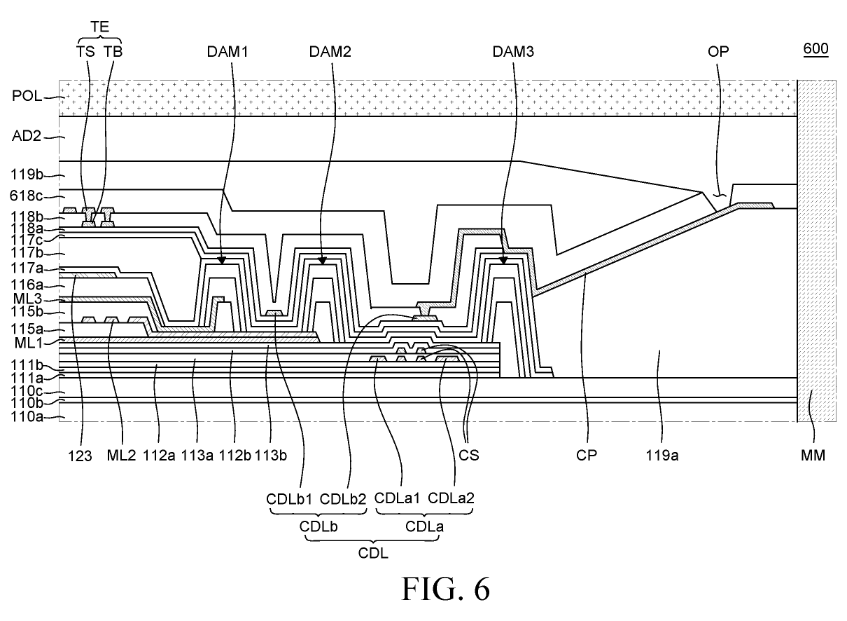

FIG. 6 is a cross-sectional view of a display device according to another embodiment of the present disclosure. A display device 600 in FIG. 6 is substantially identical in configuration to the display device 100 in FIGS. 1 to 5, except that a touch insulation layer 618c includes an opening portion OP. Therefore, repeated descriptions of the identical components will be omitted or may be briefly provided.

With reference to FIG. 6, the touch insulation layer 618c includes the opening portion OP. For example, the opening portion OP can be formed by removing the touch insulation layer 618c in a thickness direction. In addition, the opening portion OP can be continuously disposed in the touch insulation layer 618c along the outer periphery of the substrate 110. However, the present disclosure is not limited thereto.

Meanwhile, because the opening portion OP is disposed, the touch insulation layer 618c is disposed to expose a part of the conductive pattern CP. Therefore, the second bonding layer AD2 can be in contact with a part of the conductive pattern CP through the opening portion OP of the touch insulation layer 618c. For example, the second bonding layer AD2 can be in contact with a part of the conductive pattern CP exposed from the touch insulation layer 618c.

In the display device 600 according to another embodiment of the present disclosure, the second bonding layer AD2 is in contact with a part of the conductive pattern CP through the opening portion OP of the touch insulation layer 618c, thereby further minimizing contraction deformation of the third planarization layer 119b.

Specifically, in the display device 600 according to another embodiment of the present disclosure, the protective layer 119a is disposed outward of the third planarization layer 119b, and the conductive pattern CP extending to the outermost periphery of the display panel PN is disposed on the protective layer 119a. For example, the conductive pattern CP is made of a rigid material such as metal, such that the conductive pattern CP can be configured to reinforce rigidity of the protective layer 119a and the touch insulation layer 618c made of an organic material. Therefore, it is possible to minimize the concentration of stress caused by deformation by minimizing the deformation of the protective layer 119a and the touch insulation layer 618c. In this case, the touch insulation layer 618c includes the opening portion OP, and the second bonding layer AD2 is disposed to be in contact with a part of the conductive pattern CP through the opening portion OP of the touch insulation layer 618c. Therefore, the second bonding layer AD2 can be in contact with the conductive pattern CP, thereby further minimizing contraction deformation of the third planarization layer 119b made of an organic material. Therefore, in the display device 600 according to another embodiment of the present disclosure, the second bonding layer AD2 is in contact with a part of the conductive pattern CP through the opening portion OP of the touch insulation layer 618c, thereby further minimizing contraction deformation of the third planarization layer 119b and further improving the reliability of the display device 600.

The example embodiments of the present disclosure can also be described as follows:

According to an aspect of the present disclosure, a display device can include a substrate including a display area and a non-display area configured to surround the display area; a plurality of light-emitting elements disposed in the display area on the substrate; a protective layer disposed at an outermost periphery of the non-display area on the substrate and having an inclined surface inclined inward; a plurality of touch electrodes disposed on the plurality of light-emitting elements; a conductive pattern disposed on the protective layer in the non-display area; a touch insulation layer disposed on the plurality of touch electrodes and the conductive pattern; and a planarization layer disposed on the touch insulation layer.

The display device can further comprise at least one dam disposed on the substrate.

The protective layer can be disposed between an outermost peripheral dam of the at least one dam and an end of the substrate.

The protective layer can disposed outward of the outermost peripheral dam between the inside and outside of the outermost peripheral dam.

The conductive pattern can extend from a top surface of the protective layer, can be disposed to cover a part of a top surface and a part of a side surface of the outermost peripheral dam, and can extend inward from the outermost peripheral dam.

The display device can further comprise a crack detection line disposed inward of the outermost peripheral dam.

The conductive pattern can be electrically connected to the crack detection line.

The plurality of touch electrodes can comprise a touch bridge electrode; and a touch sensor electrode disposed on the touch bridge electrode.

The conductive pattern can be formed by the same process and can be made of the same material as the touch sensor electrode.

The touch insulation layer can be disposed on the conductive pattern and can have a constant thickness.

The touch insulation layer can be disposed to expose a part of the conductive pattern.

The display device can further comprise a bonding layer disposed on the touch insulation layer; and a polarizing plate disposed on the bonding layer.

The bonding layer can be in contact with a part of the conductive pattern exposed from the touch insulation layer.

The display device can further comprise a bonding layer disposed on the touch insulation layer; a polarizing plate disposed on the bonding layer; and a molding member disposed to surround lateral portions of the substrate, the protective layer, the touch insulation layer, the bonding layer, and the polarizing plate.

Breaking strength of the protective layer can be higher than breaking strength of the planarization layer.

According to another aspect of the present disclosure, a display device comprise a substrate comprising a display area in which a plurality of subpixels is disposed, a non-display area configured to surround the display area, and a bending area extending from one side of the non-display area and bent; a plurality of light-emitting elements respectively disposed in the plurality of subpixels on the substrate; a plurality of dams disposed in the non-display area on the substrate and disposed to surround the display area; a protective layer disposed outward of an outermost peripheral dam among the plurality of dams on the substrate and disposed to be spaced apart from the bending area; a plurality of touch electrodes disposed on the plurality of light-emitting elements; a conductive pattern disposed in the non-display area and disposed to extend from the inside of the outermost peripheral dam to a top surface of the protective layer; a touch insulation layer disposed on the plurality of touch electrodes and the conductive pattern; and a planarization layer disposed on the touch insulation layer.

The conductive pattern can be disposed along a part of a top surface and a part of a side surface of the outermost peripheral dam and a top surface of the protective layer.

The display device can further comprise a crack detection line disposed inward of the outermost peripheral dam.

The conductive pattern can be disposed inward of the outermost peripheral dam and can be electrically connected to the crack detection line.

The plurality of touch electrodes can comprise a touch bridge electrode; and a touch sensor electrode disposed on the touch bridge electrode.

The conductive pattern can be formed by the same process and can be made of the same material as the touch sensor electrode.

The touch insulation layer can be disposed on the conductive pattern and can have a constant thickness.

The touch insulation layer can comprise an opening portion through which a part of the conductive pattern is exposed.

The display device can further comprise a bonding layer disposed on the touch insulation layer; a polarizing plate disposed on the bonding layer; and a molding member disposed to surround lateral portions of the substrate, the protective layer, the touch insulation layer, the bonding layer, and the polarizing plate.

Breaking strength of the protective layer can be higher than breaking strength of the planarization layer.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate comprising a display area and a non-display area configured to be adjacent to the display area;
a plurality of light-emitting elements disposed in the display area on the substrate;
a protective layer disposed at an outermost periphery of the non-display area on the substrate, and having an inclined surface that is inclined inwardly;
a plurality of touch electrodes disposed on the plurality of light-emitting elements;
a conductive pattern disposed on the protective layer in the non-display area;
a touch insulation layer disposed on the plurality of touch electrodes and the conductive pattern; and
a planarization layer disposed on the touch insulation layer.

2. The display device of claim 1, further comprising:
at least one dam disposed on the substrate,
wherein the protective layer is disposed between an outermost peripheral dam of the at least one dam and an end of the substrate.

3. The display device of claim 2, wherein the protective layer is disposed outward of the outermost peripheral dam between an inside and outside of the outermost peripheral dam.

4. The display device of claim 2, wherein the conductive pattern extends from a top surface of the protective layer, is disposed to cover a part of a top surface and a part of a side surface of the outermost peripheral dam, and extends inward from the outermost peripheral dam.

5. The display device of claim 2, further comprising:
a crack detection line disposed inward of the outermost peripheral dam,
wherein the conductive pattern is electrically connected to the crack detection line.

6. The display device of claim 1, wherein the plurality of touch electrodes comprises:
a touch bridge electrode; and
a touch sensor electrode disposed on the touch bridge electrode, and
wherein the conductive pattern is formed by a same process and includes a same material as the touch sensor electrode.

7. The display device of claim 1, wherein the touch insulation layer is disposed on the conductive pattern and has a constant thickness.

8. The display device of claim 1, wherein the touch insulation layer is disposed to expose a part of the conductive pattern.

9. The display device of claim 8, further comprising:
a bonding layer disposed on the touch insulation layer; and
a polarizing plate disposed on the bonding layer,
wherein the bonding layer is in contact with a part of the conductive pattern exposed from the touch insulation layer.

10. The display device of claim 1, further comprising:
a bonding layer disposed on the touch insulation layer;
a polarizing plate disposed on the bonding layer; and
a molding member disposed to surround lateral portions of the substrate, the protective layer, the touch insulation layer, the bonding layer, and the polarizing plate.

11. The display device of claim 1, wherein a breaking strength of the protective layer is higher than a breaking strength of the planarization layer.

12. A display device comprising:
a substrate comprising a display area in which a plurality of subpixels is disposed, a non-display area configured to be adjacent to the display area, and a bending area extending from one side of the non-display area and bent;
a plurality of light-emitting elements respectively disposed in the plurality of subpixels on the substrate;
a plurality of dams disposed in the non-display area on the substrate and disposed to surround the display area;
a protective layer disposed outward of an outermost peripheral dam among the plurality of dams on the substrate, and disposed to be spaced apart from the bending area;
a plurality of touch electrodes disposed on the plurality of light-emitting elements;
a conductive pattern disposed in the non-display area and disposed to extend from an inside of the outermost peripheral dam to a top surface of the protective layer;
a touch insulation layer disposed on the plurality of touch electrodes and the conductive pattern; and
a planarization layer disposed on the touch insulation layer.

13. The display device of claim 12, wherein the conductive pattern is disposed along a part of a top surface and a part of a side surface of the outermost peripheral dam and a top surface of the protective layer.

14. The display device of claim 12, further comprising:
a crack detection line disposed inward of the outermost peripheral dam,
wherein the conductive pattern is disposed inward of the outermost peripheral dam and is electrically connected to the crack detection line.

15. The display device of claim 12, wherein the plurality of touch electrodes comprises:
a touch bridge electrode; and
a touch sensor electrode disposed on the touch bridge electrode, and
wherein the conductive pattern is formed by a same process and includes a same material as the touch sensor electrode.

16. The display device of claim 12, wherein the touch insulation layer is disposed on the conductive pattern and has a constant thickness.

17. The display device of claim 14, wherein the touch insulation layer comprises an opening portion through which a part of the conductive pattern is exposed.

18. The display device of claim 12, further comprising:
a bonding layer disposed on the touch insulation layer;
a polarizing plate disposed on the bonding layer; and
a molding member disposed to surround lateral portions of the substrate, the protective layer, the touch insulation layer, the bonding layer, and the polarizing plate.

19. The display device of claim 12, wherein a breaking strength of the protective layer is higher than a breaking strength of the planarization layer.

20. The display device of claim 12, wherein the conductive pattern is made of a rigid material, which is used to reinforce rigidity of the protective layer and the touch insulation layer.
